(19) United States
(12) Patent Application Publication
(10) Pub. No.: US 2025/0202467 A1
(43) Pub. Date: Jun. 19, 2025

(54) Systems, Devices, and Methods of a Voltage Sensor

(71) Applicant: Arm Limited, Cambridge (GB)

(72) Inventors: El Mehdi Boujamaa, Valbonne (FR); Franck Gregory Ciotti, Nice (FR); Vincent Gouin, Mandelieu (FR)

(21) Appl. No.: 18/985,294

(22) Filed: Dec. 18, 2024

(30) Foreign Application Priority Data
Dec. 18, 2023 (GB) 2319375.8

(51) Int. Cl. H03K 5/134; G01R 19/165; G01R 19/25; H03K 5/00

(52) U.S. Cl. CPC H03K 5/134; G01R 19/16576; G01R 19/2503; H03K 2005/00195; H03K 2005/00234

(57) ABSTRACT

According to one implementation, a computer system includes processing unit circuitry of one or more computer devices that include a plurality of transistors configured to a first voltage threshold, and digital voltage sensor circuitry (160) of the one or more computer devices that include at least a delay line circuit (126) including one or more digital gates (120A-N). Each of the one or more digital gates (120A-N) includes driving transistors configured to a second voltage threshold, where the digital voltage sensor circuit (160) is configured to predict voltage droop of the processing unit circuitry.

### FIELD

The present disclosure is generally related to the systems, devices, and methods of a voltage sensor circuit.

### DESCRIPTION OF RELATED ART

This section is intended to provide information relevant to understanding various technologies described herein. As the section's heading implies, this is a discussion of related art that in no way implies that the discussion is prior art. Generally, related art may or may not be considered prior art. Any statement in this section should be read in this light, and not as admission of prior art.

In the context of digital sensor design, resolution refers to the ability of a sensor to detect and distinguish between different levels of detail or information within captured data. Additionally, resolution indicates the level of detail, precision, or granularity in the output signals generated by the sensor. The sensor's ability to capture changes or events over time pertains to temporal resolution. Sensors with such high temporal resolution detect and record rapid changes or movements with greater precision. Such sensors with higher resolution are useful in scientific, industrial, and environmental monitoring applications since they provide greater measurement precision and accuracy. Also, by allowing for better analysis and interpretation of data, higher resolution can aid in extracting meaningful information from sensor outputs.

### BRIEF DESCRIPTION OF THE DRAWINGS

Implementations of various techniques are described herein with reference to the accompanying drawings. The accompanying drawings illustrate various implementations described herein and are not meant to limit implementations of various techniques described herein.

FIG. 1A is a diagram, in accordance with certain implementations.

FIG. 1B is a representation, in accordance with certain implementations.

FIG. 1C is a diagram, in accordance with certain implementations.

FIG. 1D is a representation, in accordance with certain implementations.

FIG. 2 is a diagram, in accordance with certain implementations.

FIG. 3A is a diagram, in accordance with certain implementations.

FIG. 3B is a diagram, in accordance with certain implementations.

FIG. 3C is a diagram, in accordance with certain implementations.

FIG. 4A is a diagram, in accordance with certain implementations.

FIG. 4B is a diagram, in accordance with certain implementations.

FIG. 4C is a diagram, in accordance with certain implementations.

FIG. 4D is a representation, in accordance with certain implementations.

FIG. 5 is a diagram, in accordance with certain implementations.

FIG. 6 is an example procedure, in accordance with certain implementations.

FIG. 7 is a diagram, in accordance with certain implementations.

Reference is made in the following detailed description to accompanying drawings, that form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other implementations may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, and the like), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

According to one implementation of the present disclosure, a computer system includes processing unit circuitry of one or more computer devices including a plurality of transistors configured to a first voltage threshold (corresponding to a first voltage threshold (VT)-type), and digital voltage sensor circuitry of the one or more computer devices including at least a delay line circuit including one or more digital gates. Each of the one or more digital gates includes driving transistors configured to a second voltage threshold (corresponding to a second voltage threshold VT-type), where the digital voltage sensor circuit is configured to predict voltage droop of the processing unit circuitry.

According to another implementation of the present disclosure, a method includes: identifying, by a computer system, a circuit signal path that corresponds to a circuit operation of a plurality of digital gates configured to process data between two flip-flops of a processing unit. The method further includes: identifying, by the computer system, a first voltage threshold (corresponding to a first VT-type) of respective transistors of the plurality of the digital gates, where the first voltage threshold corresponds to a gate critical path voltage threshold, and the digital voltage sensor includes one or more digital gates having a second voltage threshold (corresponding to a second VT-type), where the second voltage threshold corresponds to a voltage threshold greater than the first voltage threshold. The method further includes operating, by the digital voltage sensor of the computer system, the one or more digital gates having the second voltage threshold in a delay line of the digital voltage sensor.

According to another implementation of the present disclosure, a circuit includes a clock generator circuit, a pulse generator circuit, a delay line circuit coupled to the clock generator circuit and the pulse generator circuit. The delay line circuit is configured to predict voltage droop of a processing unit, and the delay line circuit includes a plurality of delay code capture units, where each of the delay code capture units includes a digital gate configured to a second voltage threshold greater than a first voltage threshold of the processing unit.

Schemes and techniques, as described herein, relate to an inventive voltage sensor configured to predict voltage droop of a critical path of a processing unit. In certain implementations, logic gates included in the critical path are configured with a first voltage threshold (corresponding to a first VT type) that are less sensitive to a change in voltage than logic gates included in the voltage sensor of a second volage threshold (corresponding to a second VT-type). In certain implementations, the logic gates configured with the second voltage threshold have a special gate sizing for increased voltage variation sensitivity (e.g., an increased sensitivity to a change in voltage). Additional schemes and techniques, as described herein, relate to an inventive digital voltage sensor with increased clarity in resolution to a change in voltage corresponding to a “large” (e.g., relative to a processing unit critical path voltage threshold) voltage threshold of a digital gate in one or more delay code capture units.

Certain definitions have been provided herein for reference. A droop detector measures voltage droop by a number of gate delays (e.g., a fully digital droop detector). Found in voltage regulators or power management systems, a droop detector monitors and detects fluctuations or changes in the output voltage, specifically in scenarios where there is a gradual decline or droop in the voltage level. Droop detectors may continuously monitor such output voltage of a power supply or regulator by identifying gradual declines or variations in the output voltage (e.g., commonly referred to as voltage droop). Voltage droop can occur due to changes in the load conditions or current demands in the system. In response to detecting voltage droop, the droop detector signals the voltage regulator or control system to compensate for the voltage drop.

In the context of electronics and semiconductor devices, as defined herein, “VT type” refers to the voltage threshold type of a transistor, especially in MOSFETs (Metal-Oxide-Semiconductor Field-Effect Transistors). Representing the voltage level (i.e., a voltage threshold) applied to the gate terminal that causes a transistor to switch from an off-state to an on-state, allowing current to flow between the source and drain terminals.

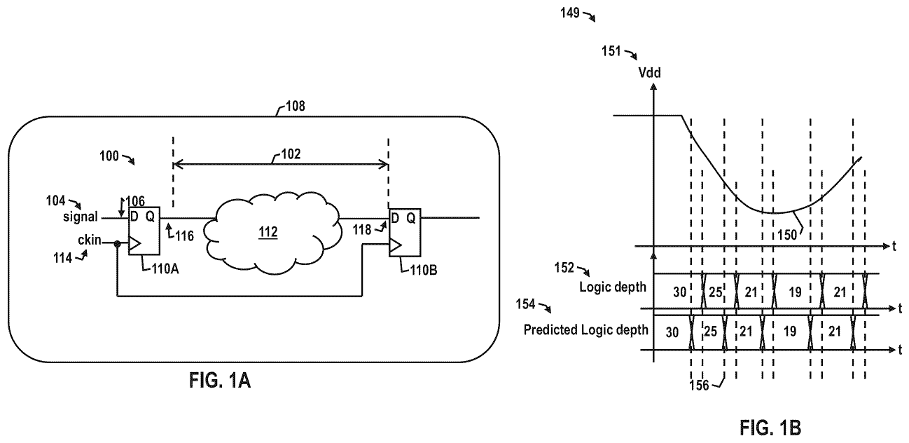

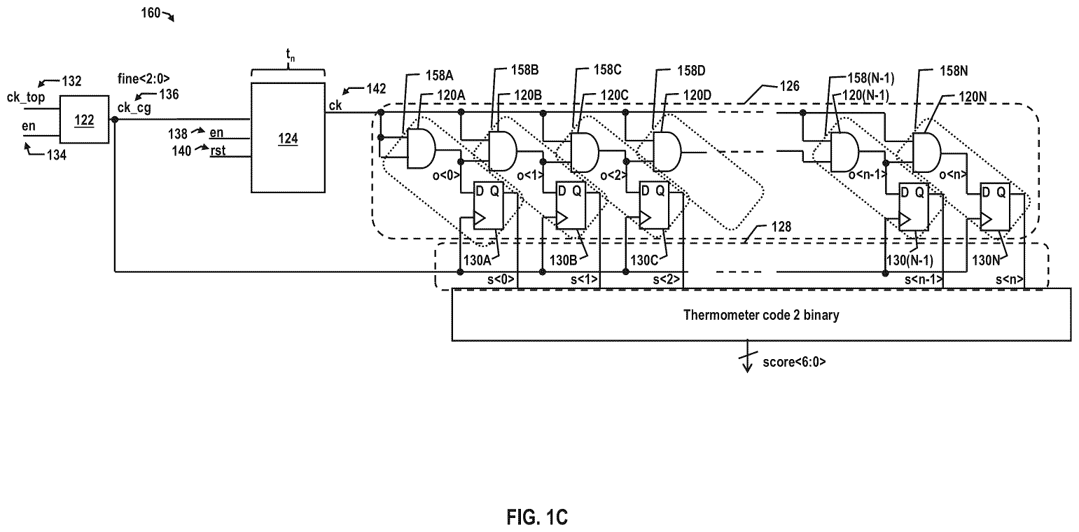

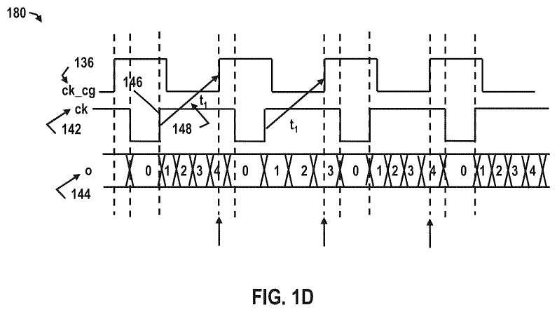

FIG. 1A is a diagram representation of an example circuit signal path 102 in an example circuit 100, in accordance with certain implementations.

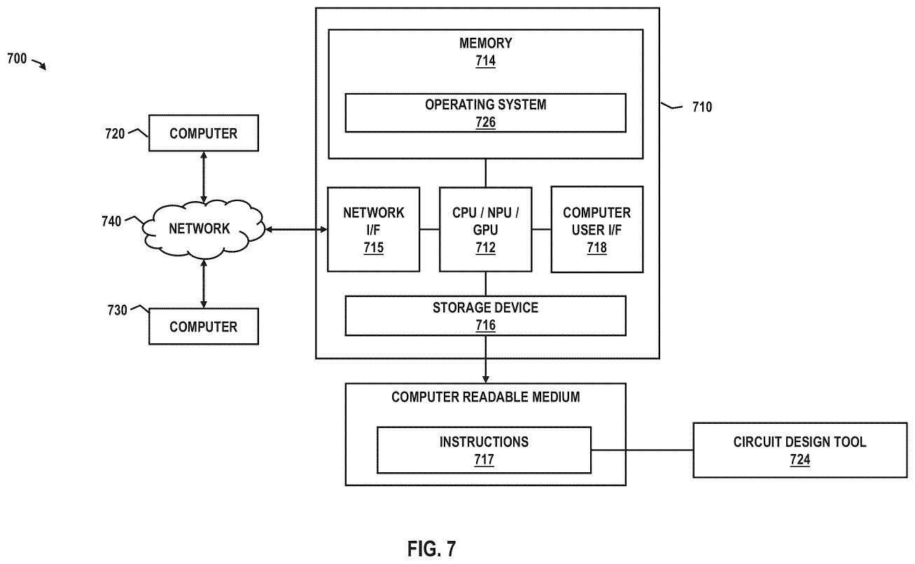

As illustrated in FIG. 1A, the example circuit signal path 102 corresponds to operation of the example circuit 100 that includes a grouping of digital gates 112 configured to process data between a first flip-flop 110A and a second flip-flop 110B of a (monitored) processing unit 108 (e.g., CPU, NPU, and/or GPU) (not shown). In certain implementations, the example circuit signal path 102 can be identified by a computer system, such as a computer system 700 (FIG. 7), as a critical path.

In the context of electronics and semiconductor devices, as defined herein, critical path and logic depth are concepts for understanding the timing and performance characteristics of a circuit, such as the example circuit 100. In the processing unit circuit 108, the example circuit signal path 102 may be the “longest” (i.e., in temporal terms) signal path that determines the maximum delay for a signal, such as signal 104, to propagate from an input to an output. Additionally, the processing unit circuit 712 can include a plurality of transistors configured to a first voltage threshold (corresponding to a first VT-type). In certain implementations, the plurality of transistors of the processing unit circuit 712 can be configured to an ultra-low voltage threshold (ULVT) type or an extra-low voltage threshold (ELVT) type.

In digital circuit design, as defined herein, ULVT and ELVT transistors are optimized for operation at extremely low voltage levels, enabling electronic circuits to function at high speeds regardless of such low voltage levels. Further, ULVT and ELVT transistors are utilized in processors or sections within processors, particularly those designed for low-power modes or specific energy-saving tasks.

As illustrated in FIG. 1A, the example circuit signal path 102 can be a grouping of digital gates 112 that impose the “most” (e.g., the longest temporal signal delay in the processing unit circuit 712) significant delay on the signal 104 as the signal 104 passes through the grouping of digital gates 112. Further, the example circuit signal path 102 can set the upper limit on the processing unit circuit's operational speed; hence, impacting the overall performance and timing constraints of the processing unit circuit 712. Thus, the signal 104 traveling along the example circuit signal path 102 may experience the greatest delay.

In certain aspects, designers focus on optimizing the critical path by reducing delays through techniques like: gate optimization (e.g., referring to the process of enhancing the speed performance, power or area efficiency, or noise characteristics of the gates), pipelining (e.g., a technique used in computer architecture and digital circuit design to improve the overall efficiency and performance of processors or systems by overlapping the execution of multiple instructions or tasks), or using faster components aiming to enhance the circuit's speed and meet performance requirements.

In digital circuit design, as defined herein, logic depth refers to the number of logic levels or stages that a signal, such as the signal 104, passes through within a circuit, such as the circuit 100, from an input to an output along a specific path, such as the example circuit signal path 102. Further, logic depth indicates the depth or complexity of the sequential logic elements along the signal path and contributes to determining the critical path's length. A longer critical path typically leads to a longer logic depth, as more logic levels introduce additional delay in signal propagation. Increasing propagation delays and affecting circuit performance can be a result of higher logic depth, making an optimization of logic depth helpful in minimizing delays and meeting timing requirements. Often influenced by the longest sequence of gates or stages, the critical path encompasses logic elements that determine the maximum delay in a circuit that aligns with a higher logic depth. Thus, reducing logic depth along critical paths can assist in minimizing delays and improving the overall speed and performance of the circuit.

As illustrated in FIG. 1A, the example circuit signal path 102 in the processing unit circuitry 712 corresponds to the grouping of digital gates 112 between a first flip-flop 110A and a second flip-flop 110B. In an operational example, at the first rising edge of an input clock signal (ckin) 114, the first flip-flop 110A shifts input 106 to an output 116. The output 116 can be processed by the grouping of digital gates 112 and, once the data is processed, output to an input 118 of the second flip-flop 110B with a given delay.

In a CPU (i.e., a Central Processing Unit is the primary component of a computer responsible for executing instructions and performing calculations required to run programs and operate the system) there can be millions of logic paths, however crucial paths, such as the example circuit signal path 102, can be where the timing of the input 118 at the second flip-flop 110B may be close to a clock period of the input clock signal (ckin) 114. In response to a voltage droop due to the grouping of digital gates 112 processing the signal 104, a signal delay (the time it takes for an electrical signal to travel from its source to its destination in an electronic system or circuit) can increase as more time is used to process the data (i.e., when voltage droops, it can increase the propagation delay of signals as transistors might take longer to switch states or become less responsive) from the input (e.g., the output 116 of the first flip-flop 110A) to the output (e.g., the input 118 of the second flip-flop 110B) of the grouping of digital gates 112. Further, while the clock period of the input clock signal (ckin) 114 is unchanged, and in response to the processing of the grouping of digital gates 112 “taking more time”, then processed data may not be caught at the output (e.g., the input 118 of the second flip-flop 110B). Such a scenario can make the processing unit circuitry 712 crash or process incorrect data.

To assist in ensuring the critical paths are met, some voltage variation margin (e.g., referring to the acceptable range or tolerance where a circuit or device can operate reliably despite fluctuations or variations in the supply voltage, and representing the allowable deviation or variation in voltage from the specified nominal voltage without adversely affecting the functionality or performance of the circuit) can be used with place and route tools (e.g., software tools that can be used in the design and manufacturing of integrated circuits (ICs) or chips that can play a role in the physical design phase of creating electronic chips, optimizing the layout of components on a semiconductor chip and establishing the paths for electrical connections between) to satisfy frequency requirements, however the circuit may use too many voltage variation margins and therefore the processing unit circuitry would not function optimally.

FIG. 1B is a graphical representation 149 of voltage droop 150 over time in relation to a logic depth 152 and an example predicted logic depth 154 as a function of voltage over time, in accordance with certain implementations. As illustrated in FIG. 1B, the logic depth 152 can correspond to an output code (e.g., 30), such as an output code of a voltage droop detector, as a function of voltage over time. In response to the voltage (e.g., Vdd 151 being the voltage level used to power the active components within the circuit, such as the circuit 100) being at operating near a nominal voltage level at time zero, the output code is 30 (e.g., that can correspond to the number of logic gates or buffers in a delay line that are propagated through by a signal before the next rising edge of the input clock signal (ckin) 114). As can be anticipated, as the Vdd 151 decreases, the output code decreases from 30 to 25, then 21, and then 19 as the Vdd 151 continues to decrease. Alternatively said, as the Vdd 151 is decreasing, the number of logic gates propagated through in a clock period is decreasing as each logic gate is getting slower (i.e., as transistors take longer to switch states or become less responsive).

In certain implementations, the output code can be predicted before the voltage droop can affect a critical path, such as the example circuit signal path 102. In a non-limiting example, in response to a critical path having a logic depth of 21 gates, the example predicted logic depth 154 indicates an anticipatory transition from 25 gates to 21 gates at time 156 (i.e., indicating the maximum gates a signal would be able to propagate through is 21). Next, the circuit, such as the circuit 100, can be made aware there could be an issue on the critical path, such as the example circuit signal path 102. Having been made aware of the possible issue on the critical path, the circuit 100 can react and take preventative measures, such as relaxing the clock frequency (i.e., slowing down the clock frequency can increase the time available for signals to propagate through the circuit). Therefore, the preventative measures can allow the grouping of digital gates 112 to complete operations within the extended time frame provided by the slower clock, reducing the likelihood of timing violations.

FIG. 1C is a diagram of an example digital voltage sensor circuit 160, in accordance with certain implementations. In various implementations, to predict an issue on a critical path, such as the example circuit signal path 102, the example digital voltage sensor circuit 160 that includes a delay line 126 of delay code capture units 158A, 158B, 158C, 158D, . . . , 158(N−1), and 158N. The delay code capture units 158A, 158B, 158C, 158D, . . . , 158(N−1), and 158N include one or more digital gates that are more sensitive to voltage changes than the grouping of digital gates 112 in the critical path of the processing unit circuitry 712 of the one or more computer devices 710, 720, and 730. Advantageously, one or more digital gates of the delay code capture units 158A, 158B, 158C, 158D, . . . , 158(N−1), and 158N (that are more sensitive to voltage change transition) can detect a voltage droop, such as the voltage droop 150, a “bit earlier” than the impact of the voltage droop on the critical path. Hence, allowing for anticipation of issues on the critical path, and a capacity to react to such issues (e.g., by reducing a clock frequency, and the like).

In one example, the delay code capture units 158A, 158B, 158C, 158D, . . . , 158(N−1), and 158N include one or more digital gates with a voltage threshold (VT) type for increased sensitivity. In another example, one or more digital gates of the delay code capture units 158A, 158B, 158C, 158D, . . . , 158(N−1), and 158N include special gate sizing for increased sensitivity.

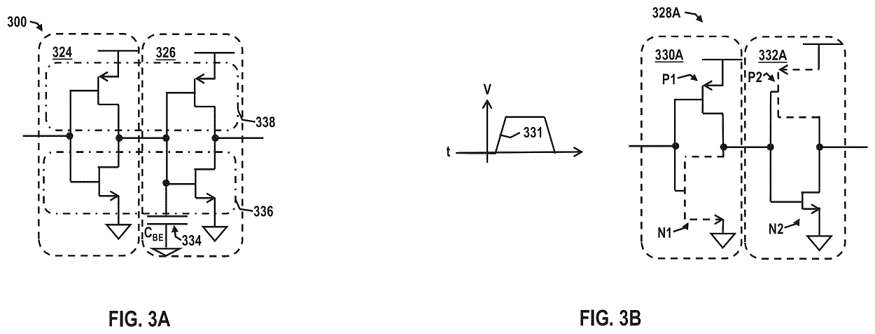

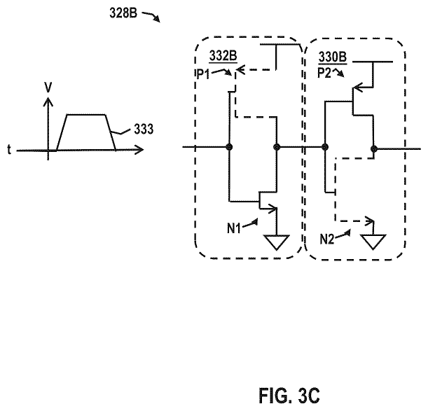

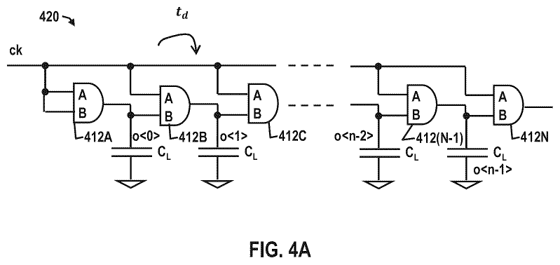

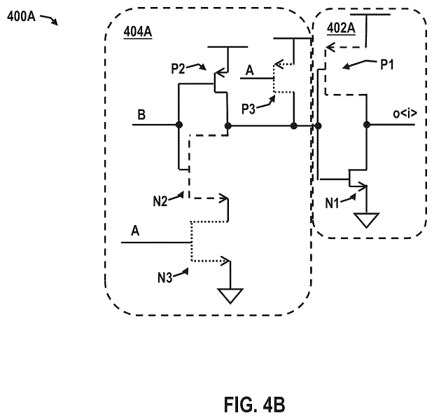

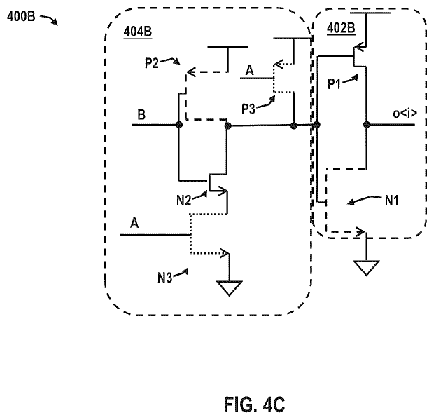

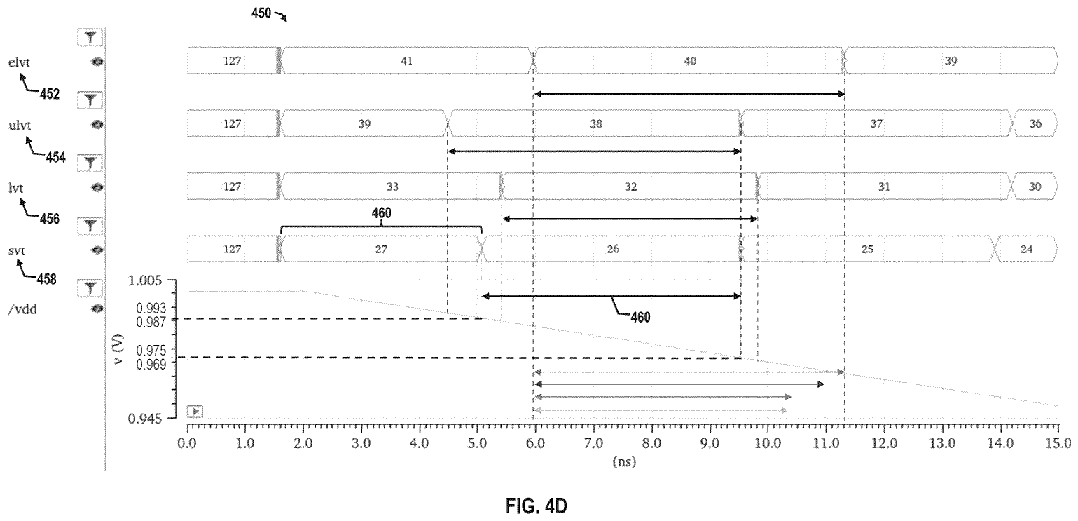

As illustrated in FIG. 1C, the example digital voltage sensor circuit 160 can be a digital voltage sensor circuitry for one or more computer devices, such as the computers 710, 720, and 730 (FIG. 7). Further, the example digital voltage sensor circuit 160 can include a delay line circuit 126 that can include digital gates, such as AND gates 120A, 120B, 120C, 120D, . . . , 120(N−1), and 120N within the delay code capture units 158A, 158B, 158C, 158D, . . . , 158(N−1), and 158N, where each of the digital gates includes driving transistors configured to a second voltage threshold (corresponding to a second VT-type) (see e.g., FIGS. 3 and 4) that can be sensitive to voltage change (as discussed in detail below). Furthermore, the second voltage threshold (corresponding to a second VT-type) of the digital gates can include a greater voltage variation sensitivity than the first voltage threshold (corresponding to a first VT-type) of the example circuit 100. Moreover, for the purposes of the present discussion, the first voltage threshold (corresponding to a first VT-type) can include one of: a low voltage threshold (LVT), an ultra-low voltage threshold (ULVT) or an extreme-low voltage threshold (ELVT) and the second voltage threshold (corresponding to a second VT-type) can include one of a standard voltage threshold (SVT) or a high voltage threshold (HVT) where the SVT and HVT include a greater voltage threshold than the LVT, the ULVT, and the ELVT. In certain implementations, the example digital voltage sensor circuit 160 can be configured to predict voltage droop of the circuit 100 as discussed above regarding FIG. 1B.

As illustrated in FIG. 1C, the delay line circuit 126 can be a component or a structure designed to introduce a controlled delay in the propagation of signals, such as output signal (ck) 142. Advantageously, the delay line circuit 126 may temporarily store or slow down signals to synchronize different parts of a circuit, manage timing, or align signals accurately. One of ordinary skill in the art understands there are various types of delay lines used in digital circuits, such as shift register-based delay lines, RC or LC delay lines, digital buffer-based delay lines (discussed below in greater detail), that can be used in the example digital voltage sensor circuit 160 to introduce a specific delay without departing from the spirt of the implementations.

Further, the example digital voltage sensor circuit 160 includes a clock generator circuit 122 and a pulse generator circuit 124 where the delay line circuit 126 may be operably coupled to the clock generator circuit 122 and the pulse generator circuit 124. As illustrated in FIG. 1C, the clock generator circuit 122 includes two inputs: a primary clock signal (ck_top) 132 that provides a base frequency and acts as a reference for the clock generator circuit 122 and an enable signal (en) 134 that can control the operation of the clock generator circuit 122. In response to the enable signal (en) 134 being active (e.g., a digital logic high state (1)), the clock generator circuit 122 can be enabled and produce a clock signal (ck_cg) 136. Alternatively, in response to the enable signal (en) 134 being inactive (e.g., a digital logic low state (0)), the clock generator circuit 122 can be designed to stop producing the clock signal (ck_cg) 136. Further, the clock generator circuit 122 can create the clock signal (ck_cg) 136 with fine-grained control (fine<2:0>) over frequency or timing characteristics. Moreover, the clock signal (ck_cg) 136 can represent a 3-bit signal (e.g., fine2, fine1, and fine0) that provides fine-grained control over the generated clock's frequency or phase. For example, the ‘fine<2:0>’ output might indicate different configurations or settings related to the frequency, phase shift, or other characteristics of the clock signal (ck_cg) 136. Such as, the clock generator circuit 122 can control frequency adjustments in smaller increments than the primary clock signal (ck_top) 132.

As illustrated in FIG. 1C, enabling the pulse generator 124 is an enable signal (en) 138 that can serve as a control signal that activates the pulse generator 124. In response to the “enable signal (en) 138 being active (often driven to a digital logic high state (1) or a digital logic low state (0), depending on the specific devices design), the enable signal (en) 138 can allow the pulse generator 124 to operate and generate pulses according to configured settings. Additionally, resetting or initializing the pulse generator 124 to a predefined state is a reset input (rst) 140. In response to the reset input (rst) 140 receiving a signal (such as a pulse, logic level change, or trigger), the reset input (rst) 140 resets the internal state of the pulse generator 124, often clearing ongoing operation or resetting configured parameters to default values. Providing the timing reference for the pulse generation process is the clock signal (ck_cg) 136 used to synchronize the generation of the clock signal (ck) 142, where the clock signal's (ck) timing or frequency is determined by the frequency of the clock signal (ck_cg) 136.

In certain implementations, the example digital voltage sensor circuit 160 can be configured to identify a circuit signal path of the processing unit circuit 712. Functionally, the circuit signal path, such as the example circuit signal path 102, can include a circuit, such as the circuit 100, where operation of a plurality of digital gates, such as the grouping of digital gates 112, can include the plurality of transistors configured to process data between two flip-flops, such as the flip-flops 110A and 110B, of the circuit 100 in approximately a clock period. Furthermore, the second voltage threshold (corresponding to a second VT-type) of one or more digital gates of the delay code capture units 158A, 158B, 158C, 158D, . . . , 158(N−1), and 158N, can include a voltage threshold greater than a voltage threshold of the example circuit signal path 102. Further, the plurality of the transistors of the grouping of digital gates 112 can be coupled in series between the two flip-flops 110A and 110B.

In an example operation, for a predetermined amount of time, the output clock signal (ck) 142 can be held at a digital logic low state (0) and outputs o<0>, o<1>, o<2>, o<n−1>, and o<n> of the AND gates 120A, 120B, 120C, 120D, . . . , 120(N−1), and 120N in the delay line circuit 126 are set to a digital logic low state (0). For instance, the setting to a digital logic low state (0) for the AND gates 120A, 120B, 120C, 120D, . . . , 120(N−1), and 120N takes one gate delay (the time taken for the clock signal (ck) 142 to propagate through a logic gate from its input to its output). Therefore, a digital logic low state (0) propagates through the delay line circuit 126 “quickly” (e.g., approximately one gate delay). Continuing with such an example, in response to the output clock signal (ck) 142 transitioning from a digital logic low state (0) to a digital logic high state (1), the AND gates 120A, 120B, 120C, 120D, . . . , 120(N−1), and 120N transition to the digital logic high state (1) value one after another. For example, after a first delay of a first AND gate 120A, output o<0> transitions to a digital logic high state (1). After a second delay of a second AND gate 120B, output o<1> transitions to a digital logic high state (1) and so on down the delay line circuit 126. In response to the clock signal (ck_cg) 136 transitioning from a digital logic low state (0) to a digital logic high state (1), there can be a propagation of the output clock signal (ck) 142 at a digital logic high state (1) into the delay line circuit 126. Further, in response to a next rising edge of the clock signal (ck_cg) 136, flip-flops 130A, 130B, 130C, . . . 130(N−1) and 130N capture a respective transition from digital logic low state (0) to a digital logic high state (1) and output their respective states as thermometer coded output 128.

In digital circuitry, as defined herein, a thermometer code is a binary encoding scheme where each bit represents a specific value or level in a sequence. In a thermometer code, each bit corresponds to a particular temperature point, similar to the markings on a thermometer where each mark represents a specific temperature. For example, a thermometer code 2 binary refers to a binary code where two bits are used to represent the thermometer code. In an example, the output score<6:0> implies a 7-bit representation (from score [6] to score [0]) and might look like: score [6]: 11, score [5]: 10, score [4]: 01, score [3]: 00, score [2]: 00, score [1]: 00, and score [0]: 00. Continuing with such an example, the score [6] bit represents the highest value in the thermometer code, followed by score [5], score [4], and so on, with decreasing binary values to indicate lower levels.

FIG. 1D is a graphical representation 180 of the clock signal (ck_cg) 136 to and the output signal (ck) 142 of the pulse generator 124 and an example output 144 of the delay line 126, in accordance with certain implementations. As illustrated in FIG. 1D, the clock signal (ck_cg) 136 triggers the pulse generator 124 to produce the clock signal (ck) 142. In response to a rising edge 146, a digital logic high state (1) propagates through the delay line 126 and the example output 144 is captured before the next rising edge of the clock signal (ck_cg) 136. Each time the rising edge 146 occurs in the clock signal (ck) 142, the flip-flops 130A, 130B, 130C, . . . , 130(N−1), and 130N, capture a digital state of the AND gates 120A, 120B, 120C, 120D, . . . , 120(N−1), and 120N shown as the example output 144 (e.g., four AND gates transitioned from a digital logic low state (0) to a digital logic high state (1) as shown in the example output 144).

In response to the output clock signal (ck) 142 transitioning from a digital logic low state (0) to a digital logic high state (1) at the rising edge 146, the AND gates 120A, 120B, 120C, and 120D, can transition to the digital logic high state (1) value one after the other in response to a measurement window (t₁) 148 (i.e., the time between the rising edge 146 and the next rising edge of the clock signal (ck_cg) 136 when the flip-flops 130A, 130B, 130C, . . . 130(N−1) and 130N are triggered to output a respective state) being “long enough” in time to transition four flip-flops to the digital logic high state as represented in the example output 144.

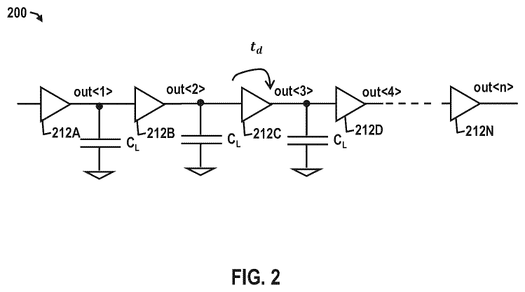

FIG. 2 is a block diagram representation of an example delay line 200 of example buffers 212A, 212B, 212C, 212D, . . . , and 212N, in accordance with certain implementations.

To better understand what is happening in terms of delay reference is made to equation (1).

$${t}_{d} = {C}_{L} \frac{dV}{I} \approx \frac{{C}_{L} {V}_{dd}}{μ {C}_{ox} \frac{W}{L} {( {V}_{dd} - {V}_{th} )}^{2}} \qquad eq . 1$$

Breaking down equation 1:

t_{d} is a gate delay or the time taken by one delay element to produce an output in response to its input.

C_{L} refers to the load capacitance or the total capacitance that an output driver in a digital circuit sees when driving a particular load.

dV/I represents the ratio of change in voltage to the change in current indicating how the voltage across a component changes concerning the current flowing through.

μCₒₓ represents the gate oxide capacitance per unit area of a transistor.

W/L ratio represents the width to length ratio of the MOSFET's channel.

Vdd denotes the drain-to-source voltage applied to the MOSFET.

Vth is the voltage threshold of the MOSFET.

Equation 1 can be used to understand a gate delay. Of particular interest can be what amount of Vdd variation makes a total number of gates decrease by one unit (i.e., as Vdd decreases to a voltage where transistors no longer switch states or become non-responsive and an input signal to the total number of gates decreases propagation by one gate unit). For example, as illustrated in FIG. 1B, there is a decrease of 4 units (e.g., from 25 to 21 gates). However, for purposes of the following discussion, for example, assume a decrease of one unit (e.g., one gate delay (t_{d})) on the left-hand side of equation 1. Correspondingly, on the right-hand side of equation 1 are the parameters that play a role in the gate delay, including the relative amount of Vdd to decrease the number of gates by one gate delay (t_{d}).

Therefore, to develop a delay line, such as the delay line 126, sensitive to a change in voltage, it is desirable to minimize the ratio of a change in Vdd (Δ) to Vdd. Currently, there exists a problem in that the best resolution of the ratio of a change in Vdd (Δ) to Vdd is 10%. In certain implementations, the ratio of a change in Vdd (Δ) to Vdd being 10% may be reduced to 1%; hence, providing for a very sensitive sensor (see e.g., discussion of FIG. 4D). Further, the lower the ratio of a change in Vdd (Δ) to Vdd, the better.

In a velocity saturated scenario, equation 1 becomes equation 2:

$${t}_{d} = {C}_{L} \frac{dV}{I} \approx \frac{{C}_{L} {V}_{dd}}{{C}_{ox} {{Wv}_{sat} ( {V}_{dd} - {V}_{th} )}^{2}} \qquad eq . 2$$

where Wvsat is the saturation velocity multiplied by the width of the transistor. Further, as may be appreciated, saturation velocity is the maximum velocity attained by charge carriers in a semiconductor material under high electric fields. In response to the electric field in the channel being greater than 10 kV/cm, saturation velocity of bulk silicon is 10⁷ cm/s. Therefore, at 3 nm length of the transistor and at 0.5V Vdd, the saturation velocity translates to ˜1666 kV/cm. Therefore, no matter which Vdd may be chosen from the DVFS table (Dynamic Voltage and Frequency Scaling table, also known as a voltage-frequency table or frequency-voltage curve; e.g., a data structure or table that maps various voltage levels to corresponding clock frequencies or performance levels and this table contains a set of entries detailing the relationship between voltage and frequency settings that the system or processor can use under different operating conditions), velocity saturation remains.

Solving for the relative variation of the delay with respect to the power supply is expressed as equation 3:

$$\frac{{dt}_{d}}{{dV}_{dd}} \approx \frac{{C}_{L}}{∝} \frac{{V}_{th}}{{( {V}_{dd} - {V}_{th} )}^{2}} \qquad eq . 3$$

where α=CₒₓWvₛₐₜ and Vₛₐₜ is the velocity saturation in the transistor and is a technological constant. In response to N gates being accumulated in a clock period, then trigger to decrement of a code is expressed as equation 4:

$$N \cdot {dt}_{d} = {t}_{d} \qquad eq . 4$$

By replacing dt_{d} and t_{d} in equation 4 by their respective expressions and simplifying, equation 5 is reached.

$$\frac{{dV}_{dd}}{{V}_{dd}} = \frac{{V}_{dd} - {V}_{th}}{{V}_{th}} \frac{1}{N} \qquad eq . 5$$

To minimize dVdd/Vdd, or alternatively stated, to maximize resolution, N, Vth, or both can be maximized (i.e., in response to the denominator of a fraction getting larger (approaching infinity), the result of the fraction gets closer to zero). Further, N can be a function of td (N gates being accumulated in a clock period) expressed equation 6:

$$N = \frac{{T}_{ck}}{{t}_{d}} \qquad eq . 6$$

By replacing N in equation 5 with the right-hand side of equation 6, equation 7 is reached:

$$\frac{{dV}_{dd}}{{V}_{dd}} = \frac{{C}_{L}}{∝ {T}_{ck}} \frac{{V}_{dd}}{{V}_{th}} \qquad eq . 7$$

To achieve a design providing a maximized resolution for dVdd/Vdd (i.e., minimizing dVdd/Vdd), C_{L} should be mostly gate capacitance where C_{L}=WLCₒₓ and thus ending up with equation 8:

$$\frac{{dV}_{dd}}{{V}_{dd}} = \frac{L}{{T}_{ck} {v}_{sat}} \frac{{V}_{dd}}{{V}_{th}} \qquad eq . 8$$

In equation 8, there are values which are restricted or unable to be changed. For example, Vsat cannot be changed, and T_{CK} is the clock period and a design constraint. Further, nominal Vdd is a design constraint as well. Accordingly, the sole variable left is the voltage threshold (VT) of the transistors used in each gate. By using a higher VT, the resolution can be maximized, and so, the sensitivity to Vdd can also be maximized. Further, equation 8 can represent that the “higher” the voltage threshold (VT) of the transistor, the “more” sensitive the transistor is with respect to a change in Vdd.

FIG. 3A is a schematic representation of an example buffer 300, in accordance with certain implementations. A buffer, in the context of electronics or computer science, as defined herein, is a fundamental component used to amplify or maintain the strength of an electrical signal as it travels through a circuit. Buffers can have a common structure as illustrated in FIG. 3A, where the example buffer 300 includes a first inverter 324 and a second inverter 326. Further, the example buffer 300 can include a pair of NMOS (N-channel Metal-Oxide-Semiconductor) transistors 336, a pair of PMOS (P-channel Metal-Oxide-Semiconductor) transistors 338 and routing capacitances (C_{BE}) 334 (the capacitances associated with the interconnects or conductive pathways used to route signals between different components or nodes in an IC or on a printed circuit board (PCB)). For each transistor, the load capacitance (C_{L}) can be expressed as C_{BE}+C_{GN}+C_{GP} where C_{GN} denotes the gate capacitance of pair of NMOS transistors 336 and C_{GP} denotes for the gate capacitance of PMOS transistors 338 and C_{BE} denotes the backend (i.e., routing) parasitic capacitance.

In equation 8, above, there is an assumption made that the capacitance of the load (C_{L}) between two buffers is the gate capacitance of the devices C_{GN}+C_{GP}. Further, equation 8 assumes that the capacitance of the load (C_{L}) between two buffers is the gate capacitance C_{GN}+C_{GP} of the devices on the following buffer. Additionally, ideally the capacitance of the load (C_{L}) is one gate capacitance. In response to driving two gate capacitances, the capacitance of the load (C_{L}) gets “larger” and this decreases the resolution of dVdd/Vdd (i.e., the numerator in equation 7 gets larger which causes the resultant to get larger). Therefore, to make capacitance of the load (C_{L}) appear like a single gate capacitance of a single transistor device is by making the gate capacitance of one transistor “so large” that the other capacitances become negligible.

FIG. 3B is a schematic representation of an example buffer 328A, in accordance with certain implementations. In some implementations, the example buffer 328A can replace the AND gates in the delay code capture units 158A, 158B, 158C, 158D, . . . , 158(N−1), and 158N of FIG. 1C. As illustrated in FIG. 3B, the example buffer 328A can include a first inverter 330A and a second inverter 332A. Further, each of the first and the second inverters 330A and 332A include an NMOS device (N1) (N2) and a PMOS device (P1) (P2) coupled in series where the NMOS device (N1) can be configured to a second voltage threshold (e.g., corresponding to a second VT-type) and the PMOS device (P1) can be configured to a first voltage threshold (e.g., corresponding to a first VT type) and the NMOS device (N2) can be configured to a first voltage threshold (e.g., corresponding to a fist VT-type) and the PMOS device (P2) can be configured to a second voltage threshold (e.g., a second VT type).

In an example operation, for transitions 331 from a digital low state (0) to a digital high state (1), the NMOS device (N1) of the first inverter 330A and the PMOS device (P2) of the second inverter 332A include the second voltage threshold (e.g., the second VT-type). In response to the transition 331 from a digital low state (0) to a digital high state (1), the NMOS device (N1) of the first inverter 330A switches on when the high voltage threshold is surpassed by the input signal voltage. Further, the output at the node between the first inverter 330A and the second inverter 332A can be a digital logic low state (0). The digital logic low state (0) can cause the PMOS device (P2) to switch on and output a delayed version of the transition 331 from a digital low state (0) to a digital high state (1).

As a result of the asymmetry of the example buffer 328A only the rising edge 331 of the input can propagate through the example buffer 328A. As the transition from the digital high state (1) to the digital low state (0) uses the relatively weak PMOS device (P1) and the relatively weak NMOS device (N2), the time taken to bring the node between the first inverter 330A and the second inverter 332A to a high value is extremely slow relative to the time taken to bring the node between the first inverter 330A and the second inverter 332A to a low value at the rising edge 331 of the input.

FIG. 3C is a schematic representation of an example buffer 328B, in accordance with certain implementations. In some implementations, the example buffer 328B can replace the AND gates in the delay code capture units 158A, 158B, 158C, 158D, . . . , 158(N−1), and 158N of FIG. 1C. As illustrated in FIG. 3C, each of a first and a second inverter 330B and 332B can include an NMOS device (N1) (N2) and a PMOS device (P1) (P2) coupled in series where the NMOS device (N2) is configured to a second voltage threshold (e.g., corresponding to a second VT-type) and the PMOS device (P2) is configured to a first voltage threshold (e.g., corresponding to a first VT type) and the NMOS device (N1) is configured to the first voltage threshold and the PMOS device (P1) is configured to the second voltage threshold.

In an example operation, for transitions 333 from a digital high state (1) to a digital low state (0), the NMOS device (N2) of the second inverter 332B and the PMOS device (P1) of the first inverter 330A are configured to the second voltage threshold. In response to the transitions 333 from a digital high state (1) to a digital low state (0), the PMOS device (P1) of the first inverter 330B switches on when the input signal voltage drops below the high voltage threshold. Further, the output at the node between the first inverter 330B and the second inverter 332B can be a digital logic high state (0). The digital logic high state (0) can cause the NMOS device (N2) to switch on and output a delayed version of the transition 333 from a digital high state (0) to a digital low state (1).

As a result of the asymmetry of the example buffer 328B only the falling edge 333 of the input can propagate through the example buffer 328B. As the transition from the digital low state (0) to the digital high state (1) uses the relatively weak NMOS device (N1) and the relatively weak PMOS device (P2), the time taken to bring the node between the first inverter 330B and the second inverter 332B to a low value is extremely slow relative to the time taken to bring the node between the first inverter 330B and the second inverter 332B to a high value at the falling edge 333 of the input.

As illustrated in FIGS. 3B and 3C, the load capacitance (C_{L}) is realized at the connection between buffers, which typically include a first inverter and a second inverter. Therefore, to improve the clarity in resolution and improve sensitivity in a delay line, such as the delay line 126, C_{GN} is made to appear as if there is only gate capacitance (C_{GN}) as the load capacitance (C_{L}) from one transistor. Therefore, to have a node which is loaded by one gate capacitance, the NMOS being NMOS device (N1) as illustrated in FIG. 3B is formed much larger than PMOS device (P1) in comparison and PMOS device (P2) is formed much larger in comparison with the NMOS device (N2). Accordingly, the capacitive load (C_{L}) is basically the gate capacitance of the NMOS device (N1) and the PMOS device (P2) as the capacitance from the routing capacitances and the NMOS device (N2) and the PMOS device (P1) are negligible. Advantageously, according to inventive aspects, the optimal condition for equation 8 can be satisfied.

FIG. 4A is a block diagram representation of an example delay line 420 of example AND gates 412A, 412B, 412C, . . . , 412(N−1), and 412N, in accordance with certain implementations. As illustrated in FIG. 4A, the example buffers 212A, 212B, 212C, 212D, . . . , and 212N in the delay line 220 of FIG. 2, have been replaced with the example AND gates 412A, 412B, 412C, . . . , 412(N−1), and 412N (producing a digital logic high state (1) only when both inputs are a digital logic high state (1)) in the example delay line 420. Like the example buffers 212A, 212B, 212C, 212D, . . . , and 212N of FIG. 2, to increase the voltage sensitivity of the example AND gates 412A, 412B, 412C, . . . , 412(N−1), and 412N the capacitive load of each AND gate can be made to appear as if it is one gate capacitance.

FIG. 4B is a schematic diagram representation of an example AND gate 400A, in accordance with some implementations. In some implementations, the example AND gate 400A can replace the AND gates in the delay code capture units 158A, 158B, 158C, 158D, . . . , 158(N−1), and 158N of FIG. 1C. In certain implementations, the AND gates 412A, 412B, 412C, . . . , 412(N−1), and 412N are AND gates, such as the example AND gate 400A. As illustrated in FIG. 4B, the example AND gate 400A includes an inverter 402A that includes a PMOS device (P1) configured to the second voltage threshold (corresponding to the second VT-type) and an NMOS device (N1). Further, the example AND gate 400A includes a NAND gate 404A that includes a first PMOS device (P2) and a second PMOS device (P3), and a first NMOS device (N2) configured to the second voltage threshold (corresponding to the second VT-type) and a second NMOS device (N3) where the inverter 402A and the NAND gate 404A are coupled in series.

In certain implementations, for transitions 131 from a digital low state (0) to a digital high state (1), the PMOS device (P1) of the inverter 402A and the NMOS device (N2) of the NAND gate 404A include the second voltage threshold (corresponding to the second VT-type) for higher resolution of dVdd/Vdd. Further, the second voltage threshold (corresponding to a second VT-type) is a higher voltage threshold than devices in the critical path. Once again, in various implementations, the first voltage threshold (corresponding to a first VT-type) comprises one of: a low voltage threshold (LVT), or an ultra-low voltage threshold (ULVT) or an extreme-low voltage threshold (ELVT), the second voltage threshold (corresponding to a second VT-type) comprises one of a standard voltage threshold (SVT), or a high voltage threshold (HVT), and the SVT, HVT includes a greater voltage threshold than the LVT, the ULVT, and the ELVT. In certain implementations, for transitions 131 from a digital low state (0) to a digital high state (1), the NMOS device (N1) of the inverter 402A and the NMOS device (N3) and the PMOS devices (P2) (P3) of the NAND gate 404A include the first voltage threshold (corresponding to the first VT-type). In certain implementations, for transitions 131 from a digital low state (0) to a digital high state (1), the NMOS device (N3) and the PMOS device (P3) of the NAND gate 404A include the LVT type for a “faster” (e.g., relative to the slower NMOS device (N2)) reset at a digital low state (0) and for “faster” (i.e., as the NMOS device (N2) and the PMOS device (P1) are relatively slower devices) pulse propagation.

FIG. 4C is a schematic diagram representation of an example AND gate 400B, in accordance with some implementations. In some implementations, the example AND gate 400B can replace the AND gates in the delay code capture units 158A, 158B, 158C, 158D, . . . , 158(N−1), and 158N of FIG. 1C. As illustrated in FIG. 4C, the example AND gate 400B includes an inverter 402B that includes a PMOS device (P1) and an NMOS device (N1) configured to the second voltage threshold (corresponding to the second VT-type). Further, the example AND gate 400B includes a NAND gate 404B that includes a first PMOS device (P2) configured to the second voltage threshold (corresponding to the second VT-type) and a second PMOS device (P3), and a first NMOS device (N2) and a second NMOS device (N3) where the inverter 402B and the NAND gate 404B are coupled in series.

In certain implementations, for the transitions 133 from a digital high state (1) to a digital low state (0), the NMOS device (N1) of the inverter 402B and the PMOS device (P2) of the NAND gate 404B are configured to the second voltage threshold (corresponding to the second VT-type) for higher resolution of dVdd/Vdd. Further, the second voltage threshold (corresponding to a second VT-type) is a higher voltage threshold than devices in the critical path. In certain implementations, for transitions 133 from a digital high state (1) to a digital low state (0), the PMOS device (P1) of the inverter 402B and the PMOS device (P3) and the NMOS devices (N2) (N3) of the NAND gate 404B are configured to the first voltage threshold (corresponding to the first VT-type). In certain implementations, for transitions 133 from a digital high state (1) to a digital low state (0), the PMOS device (P3) and the NMOS device (N3) of the NAND gate 404B include the LVT type for a “faster” (e.g., relative to the NMOS device (N1)) reset at a digital low state (0) and for “faster” (i.e., as the NMOS device (N1) and the PMOS device (P2) are slower devices) pulse propagation.

As illustrated in FIGS. 4B and 4C, and as discussed above, a reset path, that is through the A input of the PMOS device (P3) and the NMOS device (N3), uses a relatively low voltage threshold (i.e., a LVT type). In a delay line, such as delay line 126 (FIG. 1C), constructed using AND gates, the term “reset path” refers to a mechanism or a specific configuration within the delay line circuitry that allows for resetting or initializing the delay. Additionally, the reset path refers to a mechanism or a specific set of connections within the circuit that resets or clears the delayed signal back to its initial state or starting point (e.g., typically a digital logic low state (0)).

FIG. 4D is an example graphical plot 450 of voltage over time, in accordance with some implementations. As illustrated in FIG. 4D, the example graphical plot 450 of voltage over time provides the sensitivity for various voltage thresholds (i.e., ELVT 452, ULVT 454, LVT 456, and SVT 458) in a delay line, such as delay line 126, in terms of a single unit of code change 460. As illustrated, the delay line with SVT type delay elements provided the greatest sensitivity to voltage change in comparison to the other voltage thresholds (i.e., ELVT, ULVT, and LVT).

Arrow 460 illustrates a change from a 27 code to a 26 code and then after approximately 4.5 ns a change from the 26 code to a 25 code. The voltage at the change from the 27 code to the 26 code is approximately 0.988V and the voltage at the change from the 26 code to the 25 code is approximately 0.972V. Therefore, from the example graphical plot 450 it can be shown the sensitivity of the delay line with SVT type delay elements the ratio of a change in Vdd (A) to Vdd is approximately to 1.6% providing for a very sensitive sensor.

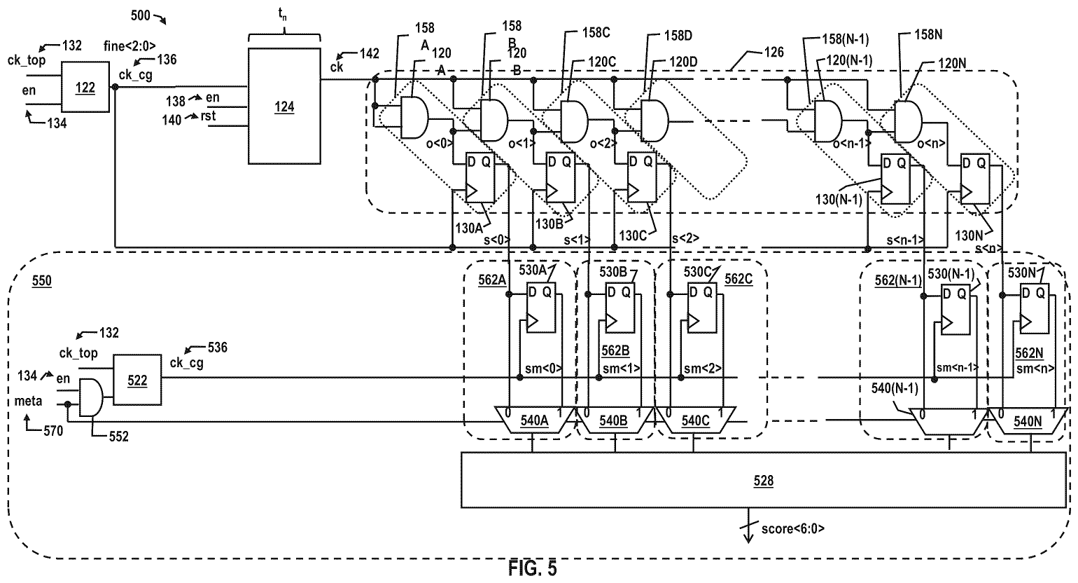

FIG. 5 is a diagram of an example digital voltage sensor circuit 500, in accordance with certain implementations. As illustrated in FIG. 5, similar elements to those of FIG. 1C are not discussed again for the sake of brevity and conciseness. As illustrated in FIG. 5, a respective code selection unit of code selection units 562A, 562B, 562C, . . . , 562(N−1), and 562N can be coupled to each of the delay code capture units 158A, 158B, 158C, 158D, . . . , 158(N−1), and 158N. Each of the code selection units 562A, 562B, 562C, . . . , 562(N−1), and 562N can include a flip-flop, such as flip-flops 530A, 530B, 530C, . . . , 530(N−1), and 530N and a multiplexer, such as multiplexers 540A, 540B, 540C, . . . , 540(N−1), and 540N. Further, the example voltage sensor circuit 500 can include a voltage droop selection circuit 550 that can include a second clock generation circuit 52; and an AND gate 552. Additionally, the voltage droop selection circuit 550 is configured to enable selection, by the code selection units 562A, 562B, 562C, . . . , 562(N−1), and 562N, of one or more respective code outputs s<0>, s<1>, s<2>, . . . , s<n−1>, s<n>, from the delay code capture units 158A, 158B, 158C, 158D, . . . , 158(N−1), and 158N.

As illustrated in FIG. 5, the AND gate 552 includes two inputs-one connected to a meta input 570 and the other input to the enable input 134. In response to both inputs of the AND gate 552 being active (for example, the meta input 570 and the enable input 134 are both a digital logic high state (1)), the AND gate 552 produces an output signal. The output signal of the AND gate 552 feeds into the clock generator 522 and can act as a gating mechanism that allows a clock signal (ck_cg) 536 to output only in response to both the meta input 570 and the enable input 134 are in specific states (e.g., a digital logic high state (1)). Further, the meta input 570 also serves as a selection signal for the multiplexers 540A, 540B, 540C, . . . 540(N−1), and 540N. Additionally, the meta input 570 determines which of the two inputs (i.e., the s<n> of the delay code capture units 158A, 158B, 158C, 158D, . . . , 158(N−1), and 158N or sm<n> of the code selection units 562A, 562B, 562C, . . . , 562(N−1), and 562N) of the multiplexers 540A, 540B, 540C, . . . 540(N−1), and 540N is selected for a thermometer coded output 528 based on the state of the meta input 570. Hence, the meta input 570 effectively controls the switching or selection between different input sources for the multiplexers 540A, 540B, 540C, . . . , 540(N−1), and 540N.

One advantage of the example digital voltage sensor circuit 500 is that in response to selecting the output (e.g., sm<n>) of the code selection units 562A, 562B, 562C, . . . , 562(N−1), and 562N) allowing a full clock cycle to pass for metastability on the 1st floor to resolve, which increases a lot at the reliability of your code at the output. Advantageously, according to inventive aspects, the digital voltage sensor circuit 500 enhances the reliability of the code at the thermometer coded output 528. Moreover, such an advantage can also be the capacity to manage potential issues of metastability. Metastability is a condition where a flip-flop or a circuit element settles in an undefined state due to timing issues when transitioning between logic levels. In response to selecting the output of the code selection units 562A, 562B, 562C, . . . , 562(N−1), and 562N, the example digital voltage sensor circuit 500 allows for a full clock cycle to pass to resolve any potential metastability that might occur in the delay line 126. Such an approach helps stabilize the signals and resolves any uncertainty in the output by providing time for the system to settle into a stable state. Correspondingly, allowing a full clock cycle for potential metastability to resolve would contribute significantly to enhancing the reliability of the code at the thermometer coded output 528. By providing such “extra” time, the example digital voltage sensor circuit 500 aims to minimize or eliminate the possibility of output errors caused by metastability issues; thus, improving the overall reliability of the example digital voltage sensor circuit 500 produced at the output of the example digital voltage sensor circuit 500. Advantageously, the voltage droop selection circuit 550 increases the data reliability in terms of mean time between failures (e.g., MTBF is a measure used to estimate the expected time between the occurrences of failures in a system or a device).

In an example operation, in response to the meta input being a digital logic low state (0), the multiplexers 540A, 540B, 540C, . . . , 540(N−1), and 540N route the output of the delay code capture units 158A, 158B, 158C, 158D, . . . , 158(N−1), and 158N and blocks the clock generator 522. Advantageously, no power is consumed on the code selection units 562A, 562B, 562C, . . . , 562(N−1), and 562N when the meta input being is a digital logic low state (0). Further, selecting the output of the delay code capture units 158A, 158B, 158C, 158D, . . . , 158(N−1) would be relatively faster as there is no waiting for a full clock cycle to pass before the output.

In another example operation, in response to the meta input being a digital logic low state (0), the multiplexers 540A, 540B, 540C, . . . , 540(N−1), and 540N route the output of the code selection units 562A, 562B, 562C, . . . , 562(N−1), and 562N and enables the clock generator 522 to output the clock signal (ck_cg) 536. While additional power is consumed by the code selection units 562A, 562B, 562C, . . . , 562(N−1), and 562N, and the output of the multiplexers 540A, 540B, 540C, . . . , 540(N−1), and 540N and the output is relatively slower (as there is a full clock cycle waiting period before the output), the data would be less susceptible to errors.

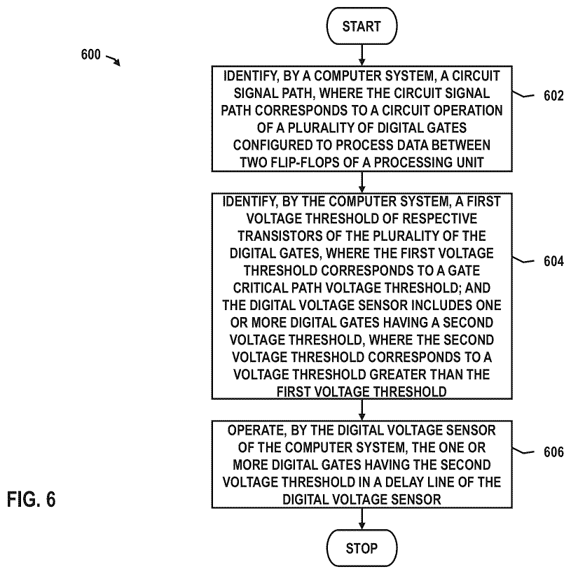

FIG. 6 illustrates an example procedure 600 for droop detection optimization of digital gates in a digital voltage sensor/detector circuit, in accordance with certain implementations. The example procedure may be implemented with reference to FIGS. 1-5 as described herein. While FIG. 6 shows a sequence of steps in the example procedure 600, one of ordinary skill in the art understands that any order of sequences is possible without departing from the spirit of the implementations. The sequence shown for the example procedure 600 is provided as an example for the reader's understanding.

In block 602, a circuit signal path can be identified by a computer system, where the circuit signal path corresponds to a circuit operation of a plurality of digital gates configured to process data between two flip-flops of a processing unit. For instance, with reference to various implementations as described in FIGS. 1 and 7, the computer system 700 can identify a critical path, such as the example circuit signal path 102, where the example circuit signal path 102 corresponds to the circuit 100 of the grouping of digital gates 112 configured to process data between the flip-flops 110A and 110B of the processing unit 108 processing unit.

In block 604, a first voltage threshold of respective transistors of the plurality of the digital gates can be identified by a computer system where the first voltage threshold corresponds to a gate critical path voltage threshold. Further, a digital voltage sensor that includes one or more digital gates having a second voltage threshold where the second voltage threshold corresponds to a voltage threshold greater than the first voltage threshold. For instance, with reference to various implementations as described in FIG. 1, a first voltage threshold, such as a first voltage threshold (e.g., corresponding to a first VT-type), of respective transistors of the grouping of digital gates 112 can be identified by the computer system 700 where the first voltage threshold corresponds to the example circuit signal path 102 voltage threshold. The first voltage threshold is less than a second voltage threshold of the digital gates 120A, 120B, 120C, 120D, . . . , 120(N−1), and 120N of the digital voltage sensor 160.

In block 606, the one or more digital gates having the second threshold voltage in a delay line of the digital voltage sensor can be operated by the digital voltage sensor. For instance, with reference to various implementations as described in FIG. 1, the digital gates 120A, 120B, 120C, 120D, . . . , 120(N−1), and 120N having the second threshold voltage in the delay line 126 of the digital voltage sensor 160 can be operated by the digital voltage sensor 160.

FIG. 7 illustrates example hardware components in the computer system 700 that may be used to optimize droop detection of digital gates in a digital voltage sensor/detector circuit. In certain implementations, the example computer system 700 (e.g., networked computer system and/or server) may include circuit design tool 724 and execute software based on the procedure as described with reference to procedure 600 in FIG. 6. In certain implementations, the circuit design tool 724 may be included as a feature of an existing compiler software program.

The circuit design tool 724 may provide generated computer-aided physical layout designs for droop detector circuits. The procedure 600 may be stored as program code as instructions 717 in the computer readable medium of the storage device 716 (or alternatively, in memory 714) that may be executed by the computer 710, or networked computers 720, 730, other networked electronic devices (not shown) or a combination thereof. In certain implementations, each of the computers 710, 720, 730 may be any type of computer, computer system, or other programmable electronic device. Further, each of the computers 710, 720, 730 may be implemented using one or more networked computers, e.g., in a cluster or other distributed computing system.

In certain implementations, the system 700 may be used with semiconductor integrated circuit (IC) designs that contain all standard cells, all blocks or a mixture of standard cells and blocks. In a particular example implementation, the system 700 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 700 may be stored in one or more of memory 714 or storage devices 716 of computer 710 or in networked computers 720, 730.

The system 700 may perform the following functions automatically, with variable user input including: determination of read current requirements/thresholds, determination of leakage current requirements/thresholds, identification of logic designs (i.e., periphery circuit designs (i.e., logic voltage thresholds, voltage threshold implant layers)), determination of a desired voltage threshold-combination, determination of minimum voltage assist requirements, identification of bit-cell types, determination of memory specific optimization modes (memory optimization mode), floor-planning, including generation of cell regions sufficient to place all standard cells; standard cell placement; power and ground net routing; global routing; detail routing and pad routing. In some instances, such functions may be performed substantially via user input control. Additionally, such functions can be used in conjunction with the manual capabilities of the system 700 to produce the target results that are required by a designer. In certain implementations, the system 700 may also provide for the capability to manually perform functions such as: cell region creation, block placement, pad, and cell placement (before and after automatic placement), net routing before and after automatic routing and layout editing. Moreover, verification functions included in the system 700 may be used to determine the integrity of a design after, for example, manual editing, design rule checking (DRC) and layout versus schematic comparison (LVS).

In one implementation, the computer 710 includes a central processing unit (CPU) 712 having at least one hardware-based processor coupled to a memory 714. The memory 714 may represent random access memory (RAM) devices of main storage of the computer 710, supplemental levels of memory (e.g., cache memories, non-volatile or backup memories (e.g., programmable or flash memories)), read-only memories, or combinations thereof. In addition to the memory 714, the computer system 700 may include other memory located elsewhere in the computer 710, such as cache memory in the CPU 712, as well as any storage capacity used as a virtual memory (e.g., as stored on a storage device 716 or on another computer coupled to the computer 710).

The computer 710 may further be configured to communicate information externally. To interface with a user or operator (e.g., a circuit design engineer), the computer 710 may include a user interface (I/F) 718 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 710 may include a network interface (I/F) 715 which may be coupled to one or more networks 740 (e.g., a wireless network) to enable communication of information with other computers and electronic devices. The computer 710 may include analog and/or digital interfaces between the CPU 712 and each of the components 714, 715, 716, and 718. Further, other non-limiting hardware environments may be used within the context of example implementations.

The computer 710 may operate under the control of an operating system 726 and may execute or otherwise rely upon various computer software applications, components, programs, objects, modules, data structures, etc. (such as the programs associated with the procedure 600 and related software). The operating system 726 may be stored in the memory 714. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 726 in the example of FIG. 7 is shown in the memory 714, but components of the software may also, or in addition, be stored at non-volatile memory (e.g., on storage device 716 (data storage) and/or the non-volatile memory (not shown). Moreover, various applications, components, programs, objects, modules, and the like may also execute on one or more processors in another computer coupled to the computer 710 via the network 740 (e.g., in a distributed or client-server computing environment) where the processing to implement the functions of a computer program may be allocated to multiple computers 720, 730 over the network 740.

In example implementations, circuit macro diagrams have been provided in FIGS. 1C, 2, 3, 4, and 5 whose redundant description has not been duplicated in the related description of analogous circuit macro diagrams. It is expressly incorporated that the same cell layout diagrams with identical symbols and/or reference numerals are included in each of embodiments based on its corresponding figure(s).

Although one or more of FIGS. 1-6 may illustrate systems, apparatuses, or methods according to the teachings of the disclosure, the disclosure is not limited to these illustrated systems, apparatuses, or methods. One or more functions or components of any of FIGS. 1-6 as illustrated or described herein may be combined with one or more other portions of another of FIGS. 1-6. Accordingly, no single implementation described herein should be construed as limiting and implementations of the disclosure may be suitably combined without departing from the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 714, the storage device 716, or both, may include tangible, non-transitory computer-readable media, or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus, or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

The subject matter of the claims is not limited to the implementations and illustrations provided herein, the intention is that modified forms of those implementations including portions of implementations and combinations of elements of different implementations be in accordance with the claims. In the development of any such implementation, there is an appreciation as in any engineering or design project, that numerous implementation-specific decisions are made to achieve the developers' specific goals, such as compliance with system-related and business-related constraints, that vary from one implementation to another. Moreover, while such a development effort is complex and time consuming, there is an appreciation for those of ordinary skill having benefit of these implementations the development would nevertheless be a routine undertaking of design, fabrication, and manufacture.

Reference has been made in detail to various implementations, examples of that are illustrated in the accompanying drawings and figures. In the above description, numerous specific details are set forth to provide a thorough understanding of the implementations provided herein. However, the implementations provided herein can be practiced without these specific details. In some other instances, well-known methods, procedures, components, circuits, and networks have not been described in detail so as not to unnecessarily obscure details of the implementations.

Although the terms first, second, and the like are used herein to describe various elements, these elements should not be limited by these terms. These terms are used to distinguish one element from another. For example, a first element can be termed a second element, and, similarly, a second element is able to be termed a first element. The first element and the second element are both elements, respectively, but they are not to be considered the same element.

The terminology used in the description of the implementations provided herein is for the purpose of describing implementations and is not intended to limit the implementations provided herein. As used in the description of the implementations provided herein and appended claims, the singular forms: “a”, “an”, and “the” are intended to include the plural forms as well, unless the context clearly indicates otherwise. The term and/or as used herein refers to and encompasses all possible combinations of one or more of the associated listed items. The terms: includes, including, comprises, and/or comprising, when used in this specification, specify a presence of stated features, integers, steps, operations, elements, and/or components, but do not preclude the presence or addition of one or more other features, integers, steps, operations, elements, components and/or groups thereof.

As used herein, the term if may be construed to mean when or upon or in response to determining or in response to detecting, depending on the context. Similarly, the phrase if it is determined or if [a stated condition or event] is detected may be construed to mean upon determining or in response to determining or upon detecting [the stated condition or event] or in response to detecting [the stated condition or event], depending on the context. The terms up and down; upper and lower; upwardly and downwardly; below and above; and other similar terms indicating relative positions above or below a given point or element are used in connection with some implementations of various technologies described herein.

While the foregoing is directed to implementations of various techniques described herein, other, and further implementations can be devised in accordance with the implementations herein, that may be determined by the claims that follow.

Although the subject matter has been described in language specific to structural features and/or methodological acts, the subject matter defined in the appended claims is not necessarily limited to the specific features or acts described above. Rather, the specific features and acts described above are disclosed as example forms of implementing the claims.

What is claimed is:

1. A computer system comprising:
processing unit circuitry of one or more computer devices comprising a plurality of transistors configured to a first voltage threshold; and
digital voltage sensor circuitry of the one or more computer devices comprising: at least a delay line circuit comprising one or more digital gates wherein each of the one or more digital gates comprises driving transistors configured to a second voltage threshold, wherein:
the digital voltage sensor circuit is configured to predict voltage droop of the processing unit circuitry.

2. The computer system of claim 1, wherein the second voltage threshold comprises a greater voltage variation sensitivity than the first voltage threshold; and
the digital voltage sensor circuitry comprises:
a clock generator circuit; and
a pulse generator circuit, wherein the delay line circuit is coupled to the clock generator circuit and the pulse generator circuit.

3. The computer system of claim 1, wherein:
the digital voltage sensor circuitry is configured to identify a circuit signal path of the processing unit circuitry;
the circuit signal path comprises a circuit operation of a plurality of digital gates of the plurality of transistors configured to process data between two flip-flops of the processing unit circuitry in approximately a clock period;
the second voltage threshold comprises a voltage threshold greater than a voltage threshold of the circuit signal path;
the plurality of the transistors is coupled in series between the two flip-flops; and
the delay line circuit comprises a plurality of delay code capture units.

4. The computer system of claim 3, wherein each of the plurality of delay code capture units comprises:
a buffer comprising first and second inverters, wherein each of the first and the second inverters comprise an NMOS device and a PMOS device coupled in series,
wherein either:
the NMOS device is configured to the second voltage threshold and the PMOS device is configured to the first voltage threshold, or
the PMOS device is configured to the second voltage threshold and the NMOS device is configured to the first voltage threshold.

5. The computer system of claim 4, wherein:
for transitions from a digital low state to a digital high state,
the NMOS device of the first inverter and the PMOS device of the second inverter are configured to the second voltage threshold.

6. The computer system of claim 4, wherein:
for transitions from a digital high state to a digital low state,
the PMOS device of the first inverter and the NMOS device of the second inverter are configured to the second voltage threshold.

7. The computer system of claim 3, wherein each of the plurality of delay code capture units comprises:
an AND gate, and
a flip-flop, wherein the AND gate comprises:
an inverter comprising:
a PMOS device configured to the second voltage threshold; and
an NMOS device; and
a NAND gate comprising:
first and second PMOS devices, wherein and first and second NMOS devices, wherein the inverter and the NAND gates are coupled in series.

8. The computer system of claim 7, wherein:
for transitions from a digital low state to a digital high state,
the PMOS device of the inverter and the first NMOS device of the NAND gate are configured to the second voltage threshold.

9. The computer system of claim 7, wherein:
for transitions from a digital high state to a digital low state,
the NMOS device of the inverter and the second PMOS device of the NAND gate are configured to the second voltage threshold.

10. The computer system of claim 1, wherein:
the first voltage threshold corresponds to a first voltage-threshold (VT)-type and the second voltage threshold corresponds to a second voltage-threshold (VT)-type;
the first VT-type comprises one of: a low voltage threshold (LVT), or an ultra-low voltage threshold (ULVT) or an extreme-low voltage threshold (ELVT);
the second VT-type comprises one of a standard voltage threshold (SVT), or a high voltage threshold (HVT);
the SVT, HVT comprises a greater voltage threshold than the LVT, the ULVT, and the ELVT.

11. The computer system of claim 1, further comprising:
a respective code selection unit of a plurality of code selection units coupled to each of the delay code capture units, wherein:
each of the code selection units comprises:
a flip-flop; and
a multiplexer.

12. The computer system of claim 1, further comprising:
a voltage droop selection circuit comprising:
a second clock generation circuit; and
an AND gate, wherein:
the voltage droop selection circuit is configured to enable selection, by the plurality of code selection units, of one or more respective code outputs from the plurality of delay code capture units.

13. A method comprising:
identifying, by a computer system, a circuit signal path, wherein the circuit signal path corresponds to a circuit operation of a plurality of digital gates configured to process data between two flip-flops of a processing unit;
identifying, by the computer system, a first voltage threshold of respective transistors of the plurality of the digital gates, wherein:
the first voltage threshold corresponds to a gate critical path voltage threshold; and
the digital voltage sensor comprises one or more digital gates having a second voltage threshold, wherein the second voltage threshold corresponds to a voltage threshold greater than the first voltage threshold;
operating, by the digital voltage sensor of the computer system, the one or more digital gates having the second voltage threshold in a delay line of the digital voltage sensor.

14. The method of claim 13, wherein the one or more digital gates of the digital voltage sensor comprises one of buffers or AND gates.

15. A circuit comprising:
a clock generator circuit;
a pulse generator circuit;
a delay line circuit coupled to the clock generator circuit and the pulse generator circuit, wherein:
the circuit is configured to predict voltage droop of a processing unit, and
the delay line circuit comprises a plurality of delay code capture units, wherein each of the delay code capture units comprises:
a digital gate configured to a second voltage threshold greater than a first voltage threshold of the processing unit.

16. The circuit of claim 15, wherein:
the second voltage threshold comprises a greater voltage variation sensitivity than the first voltage threshold;
the first voltage threshold comprises a voltage threshold of one or more transistors in the processing unit;
the digital gate comprises a buffer;
the buffer comprising first and second inverters; and
each of the first and the second inverters comprise an NMOS device and a PMOS device coupled in series.

17. The circuit of claim 16, wherein:
for transitions from a digital low state to a digital high state,
the NMOS device of the first inverter and the PMOS device of the second inverter are configured to the second voltage threshold; and
for transitions from the digital high state to the digital low state,
the PMOS device of the first inverter and the NMOS device of the second inverter are configured to the second voltage threshold.

18. The circuit of claim 15, wherein:
transistor sizes of the digital gates configured to the second voltage threshold are greater than transistor sizes of the second voltage threshold.

19. The circuit of claim 15, wherein:
the first voltage threshold corresponds to a gate critical path voltage threshold of the processing unit,
the gate critical path voltage threshold corresponds to a voltage threshold of a plurality of digital gates configured to process data between two flip-flops of the processing unit in approximately a clock period; and
the plurality of digital gates is coupled in series between the two flip-flops.

20. The circuit of claim 15, further comprising:
a respective code selection unit of a plurality of code selection units coupled to each of the delay code capture units, wherein:
each of the code selection units comprises:
a flip-flop; and
a multiplexer.

21. The circuit of claim 15, wherein:
the second voltage threshold comprises a greater voltage variation sensitivity than the first voltage threshold;
the first voltage threshold comprises a voltage threshold of one or more transistors in the processing unit; and
the digital gate comprises an AND gate, wherein the AND gate comprises:
an inverter comprising a PMOS device and an NMOS device; and
a NAND gate comprising first and second PMOS devices and first and second NMOS devices, wherein the inverter and the NAND gates are coupled in series.

22. The circuit of claim 21, wherein:
for transitions from a digital low state to a digital high state,
the PMOS device of the inverter and the first NMOS device of the NAND gate are configured to the second voltage threshold; and
for transitions from the digital high state to the digital low state,
the NMOS device of the inverter and the second PMOS device of the NAND gate are configured to the second voltage threshold.

23. The circuit of claim 21, wherein:
the first voltage threshold corresponds to a first voltage-threshold (VT)-type and the second voltage threshold corresponds to a second voltage-threshold (VT)-type;
the second VT-type comprises one of a standard voltage threshold (SVT), or a high voltage threshold (HVT);
the first VT-type comprises one of: a low voltage threshold (LVT), or an ultra-low voltage threshold (ULVT) or an extreme-low voltage threshold (ELVT);
the SVT and HVT comprises a greater voltage threshold than the LVT, the ULVT, and the ELVT; and
the first VT-type is configured for voltage operation at or below the critical path voltage operation.

24. The circuit of claim 23, wherein:
the SVT comprises a greater voltage threshold than the HVT;
the LVT comprises a greater voltage threshold than the ULVT and the ELVT; and
the ULVT comprises a greater voltage threshold than the ELVT.

25. The circuit of claim 20, further comprising:
a voltage droop selection circuit:
a second clock generation circuit; and
an AND gate, wherein:
the voltage droop selection circuit is configured to enable selection, by the plurality of code selection units, of one or more respective code outputs from the plurality of delay code capture units.
